(19) United States
(12) Patent Application Publication
(10) Pub. No.: US 2002/0018360 A1
(43) Pub. Date: Feb. 14, 2002

(54) Integrated memory having memory cells with a magnetoresistive storage effect

(76) Inventor: Udo Hartmann, Munchen (DE)

Correspondence Address: LERNER AND GREENBERG, P.A., Post Office Box 2480, Hollywood, FL, 33022-2480, US

(21) Appl. No.: 09/902,342

(22) Filed: Jul. 10, 2001

(30) Foreign Application Priority Data
Jul. 10, 2000 (DE) 100 33 486.5

(51) Int. Cl. G11C 11/00

(52) U.S. Cl. 365/158

(57) ABSTRACT

An integrated memory is described which has memory cells with a magnetoresistive storage effect, which are each connected to a common electrical line. The line has a first interconnect and a second interconnect, and also a first terminal and a second terminal, between which the line is connected to the memory cells. The first interconnect is connected to a current source at the first terminal and the second interconnect is connected to a further current source at the second terminal, for writing data to one of the memory cells. This enables relatively high reliability of the memory with regard to the data to be stored.

### BACKGROUND OF THE INVENTION

Field of the Invention

The present invention relates to an integrated memory having memory cells with a magnetoresistive storage effect.

For storing data signals memory cells with a magnetoresistive storage effect generally have ferromagnetic layers whose state can be altered. The storage effect is generally known as so-called giant magnetoresistive (GMR effect) or tunneling magnetoresistive (TMR) effect. In this case, the electrical resistance of a memory cell of this type is dependent on the magnetization in the ferromagnetic layers.

Integrated memories having memory cells of this type, also referred to as so-called magnetoresistive random access memories (MRAMs), are often constructed similarly to, for example, integrated memories of the DRAM type. Memories of this type generally have a memory cell configuration with row lines and column lines running essentially parallel among one another, the row lines usually running transversely with respect to the column lines.

A MRAM memory of this type is disclosed in International Patent Disclosure WO 99/14760, where the memory cells in each case along row lines are switched between the respective row lines and respective column lines and are electrically connected to the respective column line and row line. In this case, the memory cells with a magnetoresistive storage effect have a higher impedance than the row lines and column lines. The column lines are connected to a sense amplifier for reading out a data signal of one of the memory cells. For the read-out, the current that can be detected on the column line is measured.

Unlike in a DRAM memory, in a MRAM memory of this type there are no diodes or transistors that, for reading out a data signal, connect the memory cells to the respective column line in a manner dependent on the addressing. As a result, in particular, advantages are obtained in the geometrical configuration of the memory cells. In particular, a stacked configuration of the memory cells makes it possible to save space in the configuration of the memory cells. However, as a result, a certain leakage current occurs through the memory cells which are connected to a selected row line or column line but are not to be read from or written to.

In order to write information to one of the memory cells, it is generally necessary to generate a magnetic field for the relevant memory cell, which magnetic field puts a magnetic layer of the memory cell into a corresponding state. The magnetic field is generated by respective currents (or by superposition of their magnetic fields) which are fed into the connected row line and column line at a respective feed-in point. On account of the leakage currents through the memory cells connected to the affected row line and column line, which accumulate with the number of memory cells, the current at the feed-in point is to be set within a certain tolerance range so as to ensure that the required current for writing to one of the memory cells is fed in for all the memory cells along the common row line or column line. The consequence of this is, in particular, that a driving current source or a current driver has to be given appropriately large dimensions. Moreover, a current or magnetic field of different intensity or strength is written to the memory cells depending on their position relative to the feed-in point. Overall, the reliability of the memory with regard to the data to be stored can be impaired if, through aging for example, the leakage current of one or more memory cells increases and such a tolerance range is dimensioned relatively tightly.

### SUMMARY OF THE INVENTION

It is accordingly an object of the invention to provide an integrated memory having memory cells with a magnetoresistive storage effect which overcomes the above-mentioned disadvantages of the prior art devices of this general type, in which a relatively high reliability with regard to the data to be stored is made possible.

With the foregoing and other objects in view there is provided, in accordance with the invention, an integrated memory. The integrated memory contains a common electrical line having a first interconnect, a second interconnect, a first terminal, and a second terminal. Memory cells are provided having a magnetoresistive storage effect, each of the memory cells is connected to the common electrical line at coupling nodes between the first and second terminals. A first current source is connected to the first interconnect at the first terminal and a second current source is connected to the second interconnect at the second terminal. The first and second current sources are provided for writing information to one of the memory cells.

The object is achieved by the integrated memory having memory cells with the magnetoresistive storage effect, which are each connected to the common electrical line. In which the line has the first interconnect, the second interconnect, the first terminal and the second terminal and is connected to the memory cells between the terminals at coupling nodes. The first terminal at the first interconnect is connected to the first current source and the second terminal at the second interconnect is connected to the second current source, for writing information to one of the memory cells.

The use of two current sources which are connected to the common line at opposite ends relative to the memory cells has the effect of producing, for writing information to one of the memory cells, from the standpoint of the memory cells a significantly more uniform profile of the magnetic field that is to be effected and is necessary for writing information. The currents fed in by the first current source and the second current source produce a magnetic field resulting from the superposition for the relevant memory cell.

This advantageously avoids the situation where a current to be fed in at an individual location has to be set within a relatively large tolerance range in order to compensate for the leakage currents of the memory cells which are connected to the line and are not selected for a writing operation. If such a tolerance range is dimensioned relatively tightly, for example, then the reliability of the integrated memory with regard to the data to be stored can be impaired if, through aging for example, the leakage current of one or more memory cells increases. Since, in the case of the invention, the resulting effective current for generating the magnetic field has a more uniform profile, this is largely avoided, as a result of which the integrated memory has increased reliability with regard to the data to be stored.

In a development of the invention, the memory cells are disposed in a memory cell array having column lines and row lines. In this case, the memory cells are each connected to one of the column lines and one of the row lines. In this case, the common line is embodied as one of the row lines or the column lines. In this case, it is advantageous that all the row lines and the column lines of the integrated memory each have two interconnects which are in each case connected to a current source for writing information. However, it is also possible for either the row lines or the column lines to be configured in a manner according to the invention.

The first current source and the second current source can each be given smaller dimensions than an individual current source that feeds in a current only at a single feed-in point of the relevant line. The two current sources to be provided can be disposed at a suitable location, for example at the edge of the memory cell array. In a manner corresponding to the course of the row lines and/or column lines, the current sources are in this case situated on opposite sides of the memory cell array. In addition, the first and second terminals are also disposed on opposite sides of the memory cell array.

In order to obtain a largely uniform profile of the effective current, it is advantageous for each of the current sources to feed in a current with an essentially identical magnitude. It is advantageous, therefore, for the current sources to be largely identical.

Other features which are considered as characteristic for the invention are set forth in the appended claims.

Although the invention is illustrated and described herein as embodied in an integrated memory having memory cells with a magnetoresistive storage effect, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is an illustration of a general embodiment of an integrated MRAM memory;

FIG. 2 is an illustration of an exemplary embodiment of the integrated MRAM memory according to the invention;

FIG. 3 is a graph of a current profile of the memory according to FIG. 2;

FIG. 4 is an illustration of the general embodiment of the memory connected to an individual current source; and

FIG. 5 is a graph of the current profile of the memory according to FIG. 4.

### DESCRIPTION OF THE PREFERRED EMBODIMENTS

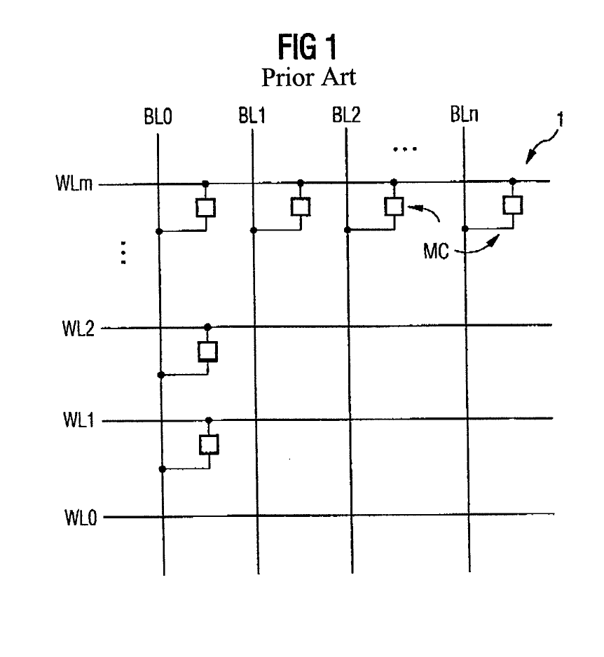

In all the figures of the drawing, sub-features and integral parts that correspond to one another bear the same reference symbol in each case. Referring now to the figures of the drawing in detail and first, particularly, to FIG. 1 thereof, there is shown a general embodiment of a magnetoresistive random access memory (MRAM) having memory cells MC with a magnetoresistive storage effect. All known GMR/TMR elements are suitable as memory cells provided that they have a higher impedance than column lines, in this case designated as bit lines BL0 to BLn, and row lines, in this case designated as word lines WL0 to WLm. The memory in this case has an exemplary number of word lines and bit lines. The memory cells MC, which are disposed in a matrix-type memory cell array 1, are each switched between one of the bit lines BLO to BLn and one of the word lines WL0 to WLm.

In order to write an item of information or a data signal to one of the memory cells MC the corresponding connected bit line and word line are connected to a respective current source, which are not illustrated in FIG. 1. As a result of the currents flowing in the corresponding lines, a superposed magnetic field is generated at the crossover point between the bit and word lines. The relevant memory cell MC is disposed at the crossover point, which magnetic field puts a magnetic layer of the relevant memory cell in a specific state.

In order to read out a data signal from one of the memory cells MC, the corresponding bit line is connected for example to a sense amplifier, which is likewise not illustrated in FIG. 1. For the read-out, the relevant word line is driven and has a predetermined potential applied to it, so that a current flow occurs through the memory cell MC to be read.

All the other word lines are put at reference-ground potential, for example. The current flow through the memory cell is detected by the sense amplifier on the connected bit line.

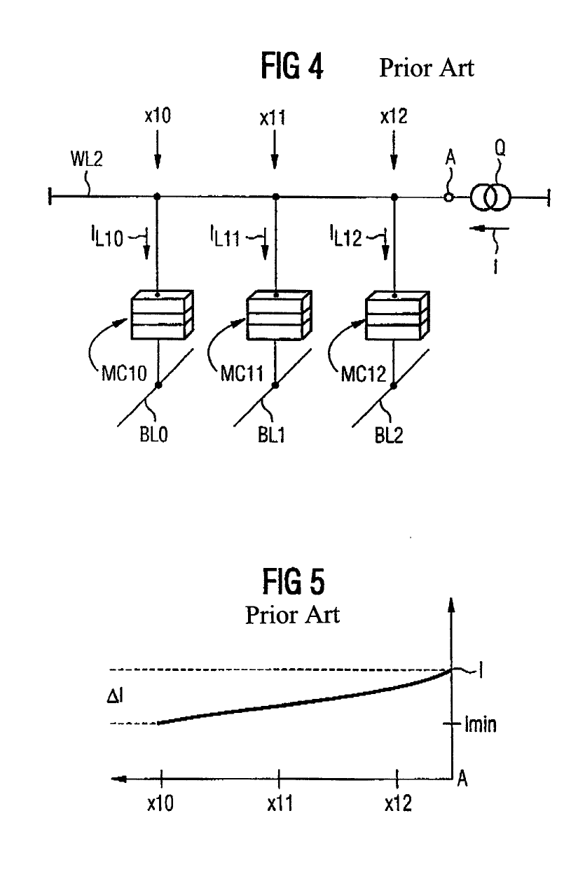

FIG. 4 shows, in an embodiment of the memory according to FIG. 1, a word line WL2 to which the memory cells MC10, MC11 and MC12 are connected. The latter are respectively connected to the bit lines BLO, BL1 and BL2. In order to write a data signal to the memory cell MC10, for example, the word line WL2 is connected to a current source Q. The same is carried out correspondingly for the column line BLO. The current source Q drives a current I in the line WL2. Since the memory cells MC10 to MC12 are not connected to the word line WL2 via a switching device, such as, for example, transistors, a leakage current IL10, IL11 and IL12, respectively, occurs in the memory cells MC. To ensure that the data signal is properly written to the memory cell MC10, a minimum current Imin is required at the memory cell MC10 in order to generate a corresponding magnetic field. In order to achieve the current Imin, it is necessary for an increased current I to be fed in at a feed-in point A, in order to compensate for the leakage currents IL11 and IL12.

An exemplary diagrammatic current profile for the current I according to FIG. 4 is shown in FIG. 5. On account of the leakage currents IL11 and IL12, the current I at the location x10, at which the memory cell MC10 is connected to the word line WL2, is reduced by the magnitude A1. Therefore, in accordance with the number of memory cells connected to the word line WL2, a current I increased by the sum of the leakage currents must be fed in in order to generate the current Imin at the memory cell MC10. The current source Q therefore has to be given correspondingly large dimensions.

The memory cells MC10 to MC12 are written to to different extents by the current source Q in accordance with the locally different currents or magnetic fields. For the case where a leakage current of one of the memory cells increases on account of aging, for example, the reliability of the memory with regard to the data to be stored can be impaired, in particular if the minimum current Imin required is undershot at a memory cell to be written to.

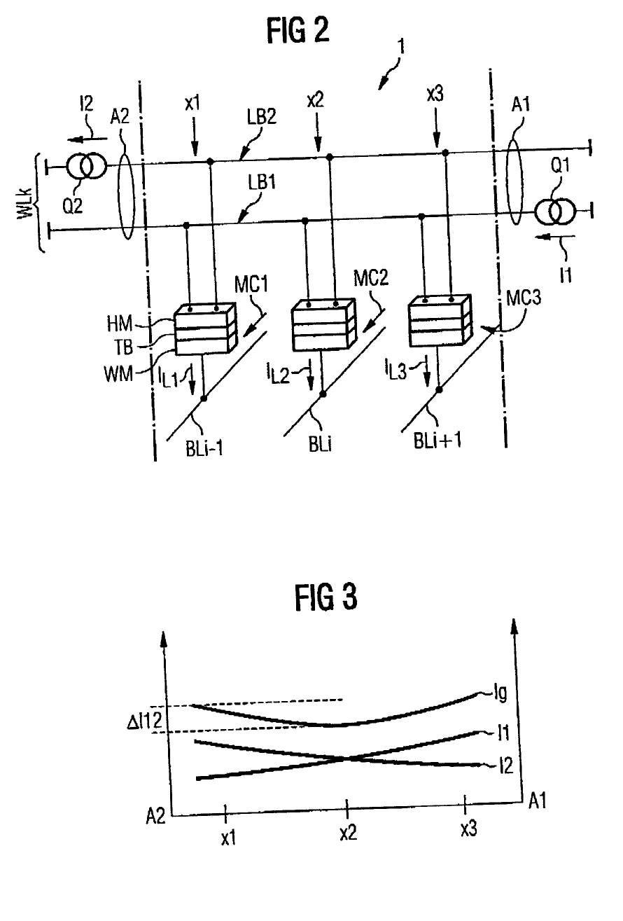

FIG. 2 shows a detail from a simplified illustration of an integrated memory according to the invention, having a word line WLk and the bit lines Bli−1, Bli and Bli+1, which are disposed in the memory cell array 1 according to the structure as shown in FIG. 1. The magnetoresistive memory cells MC1 to MC3 are each connected to the common word line WLk. In this case, the memory cells MC1 to MC3 are connected to the word line WLk at the coupling nodes x1 to x3. The word line WLk has a first conductor track or interconnect LB1 and a second conductor track or interconnect LB2. The word line WLk has terminals A1 and A2; between the terminals A1 and A2, the word line WLk is connected to the memory cells MC1 to MC3 at the coupling nodes x1 to x3. The interconnect LB1 is connected to a first current source Q1 at the terminal A1. The second interconnect LB2 is connected to a second current source Q2 at the terminal A2. In this case, the first current source Q1 drives the current I1 and the second current source Q2 drives the current I2. When a data signal is written to one of the memory cells MC1 to MC3, the interconnects LB1, LB2 are in each case connected to one of the current sources Q1 and Q2 respectively. A respective leakage current IL1 to IL3 occurs in the memory cells in this case.

In the exemplary embodiment shown, the terminal A1 and the terminal A2 are situated on opposite sides of the memory cell array 1. The first current source Q1 and the second current source Q2 are likewise disposed on opposite sides of the memory cell array 1. The magnitudes of the currents I1 and I2 are essentially identical. This is achieved by the current sources Q1 and Q2 having a largely identical circuit construction.

The circuit configuration illustrated in FIG. 2 with regard to the word line WLk can likewise be analogously applied to one of the bit lines Bli−1 to BLi+1, since the latter are likewise each connected to a corresponding current source for the writing of a data signal to one of the connected memory cells. In this case, the magnetic fields generated by the corresponding word line and bit line form a superposed resultant magnetic field for programming the corresponding memory cell.

FIG. 3 diagrammatically shows an exemplary current profile of the memory according to FIG. 2. The currents I1 and I2 are fed in at the terminals A1 and A2, respectively. The currents I1 and I2 generate a resultant magnetic field according to the superposition principle, the magnetic field being represented by the effective current Ig≅I1+I2. On account of the leakage currents IL1 and IL3, the effective current Ig at the coupling node x2 has a deviation A112 from the magnitude Ig at the terminals A1 and A2, respectively. The use of the two current sources Q1 and Q2 respectively situated at opposite ends of the word line WLk produces, through the superposition principle, a profile of the effective current Ig that is significantly more uniform in comparison with the current profile shown in FIG. 5. In this case, the deviation ΔI12 is essentially halved compared with the deviation ΔI according to FIG. 5. The reliability of the memory with regard to the data to be stored is also largely preserved if, on account of aging for example, a leakage current of one of the memory cells MC1 to MC3 increases, since there is a larger distance from the current Imin.

The contact-connections of the word line WLk and of the bit lines Bli−1 to Bli+1 to the memory cells MC1 to MC3 are only represented symbolically in each case in FIG. 2 (correspondingly in FIG. 4). Physically, the lines are disposed directly above the memory cells MC since the magnetic field generated by the respective current is crucial for the respective writing operation. The memory cells MC shown are each constructed from three layers here. They have a hard-magnetic layer HM, a tunnel barrier TB and a soft-magnetic layer WM. During a writing operation, the respective soft-magnetic layer WM is in this case put into a specific state by the magnetic field generated. Using this state, the stored information can be read from the memory cell MC at a later time.

I claim:

1. An integrated memory, comprising:
a common electrical line having a first interconnect, a second interconnect, a first terminal, and a second terminal;
memory cells each having a magnetoresistive storage effect, each of said memory cells connected to said common electrical line at coupling nodes between said first and second terminals;
a first current source connected to said first interconnect at said first terminal; and
a second current source connected to said second interconnect at said second terminal, said first and second current sources provided for writing information to one of said memory cells.

2. The integrated memory according to claim 1, including a memory cell array having column lines and row lines, said memory cells are disposed in said memory cell array and each of said memory cells is connected to one of said column lines and one of said row lines, said common electrical line formed from one of said row lines or said column lines.

3. The integrated memory according claim 2, wherein said first terminal and said second terminal are disposed on opposite sides of said memory cell array.

4. The integrated memory according to claim 2, wherein said first current source and said second current source are disposed on opposite sides of said memory cell array.

5. The integrated memory according to claim 1, wherein said first current source and said second current source have an identical circuit construction.
